(19) United States
(12) Patent Application Publication
(10) Pub. No.: US 2013/0314920 A1
(43) Pub. Date: Nov. 28, 2013

(54) Direct Heat Sink Technology for LEDs and Driving Circuits

(71) Applicants: Myung Ho Park, Boca Raton, FL (US); Luis Rosado, Miramar, FL (US)

(72) Inventors: Myung Ho Park, Boca Raton, FL (US); Luis Rosado, Miramar, FL (US)

(21) Appl. No.: 13/481,147

(22) Filed: May 25, 2012

(51) Int. Cl. H05K 7/20; F21V 29/00

(52) U.S. Cl. 362/249.02; 174/252

(57) ABSTRACT

Thermally radiating heat sinks are soldered directly beneath individual LEDs and other heat generating electronic components on the opposite side of an FR4 circuit board and thermally coupled to the heat source through multiple micro-vias. The micro-vias are filled with solder in order to increase the thermal transmission of heat energy through the circuit board to the heat sinks The circuit board thickness is minimized to further reduce the thermal resistance of the transmission path. The method employed facilitates the heat transfer away from high-powered LEDs and other heat generating circuitry without spreading the heat energy to thermally sensitive electronic circuits and without the need for expensive substrates commonly employed to dissipate heat in electronic circuits. The method is adapted for LED lighting circuits and preferably to industry standard bulb sizes such as MR11, MR16, R20, PAR30, PAR38, and PAR56.

### FIELD OF THE INVENTION

This invention relates to illumination devices incorporating LEDs (light emitting diodes). The use of LEDs in illumination systems is well known. These devices are increasingly useful for providing ambient lighting, task lighting, and accent lighting as LED technology advances and LEDs become more efficient and higher powered. LED lighting is a fast growing segment of the lighting industry due to the efficiency, reliability and longevity of LEDs. Adaptations of the current invention make it especially useful in industry standard bulb sizes such as MR11, MR16, R20, PAR30, PAR38, and PAR56. Product usage applications also include interior and exterior signage, cove lighting, architectural lighting, display case lighting, under water lighting, marine lighting, landscape lighting, highway lighting and many others.

### INCORPORATION BY REFERENCE AND OTHER REFERENCES

Applicant incorporates by reference the following:
Nichia Corporation NS6W183AT White LED Data Sheet.
Lumileds Lighting, LLC Publication No. ABO5 (Nov 2001) “Thermal Design Considerations for Luxeon Power Light Sources.”
Osram Opto Semiconductors Application Note (Oct. 2008) “Thermal Management of Golden Dragon LED.”
Mentor Graphics Corp. White Paper 59097 “Thermal Characterization Confirms Real-World LED Performance.”
Texas Instruments Application Note 1520, Literature Number SNVA183A “A Guide to Board Layout for Best Thermal Resistance for Exposed Packages.”
Electronics Cooling Magazine, August 2006 Issue “Thermal Conductivity of Solders” by Jim Wilson: http://www.electronics-cooling.com/2006/08/thermal-conductivity-of-solders;

### BACKGROUND OF THE INVENTION

LEDs are current-controlled devices in the sense that the intensity of the light emitted from an LED is related to the amount of current driven through the LED. FIG. 1 shows a typical relationship of relative luminosity to forward current in an LED. The longevity or useful life of LEDs is specified in terms of acceptable long-term light output degradation. Light output degradation of an LED is affected by the operating junction temperature of the LED die. The lower the junction temperature of the LED, the more enhanced its performance, and the longer its life. In fact, the LED can be destroyed if the die temperature exceeds the manufacturer's specified absolute maximum for the device. An examination of a typical LED data sheet such as the Nichia Corporation NS6W183AT White LED Data Sheet, incorporated herein by reference, shows that the absolute maximum junction temperature for this white LED is 135° C.

FIG. 2 shows another advantage to keeping the LED junction temperature low. The relative light output of an LED is adversely affected by the operating junction temperature. As can be seen in FIG. 2, as the junction temperature of the LED increases, its relative light output decreases. It is therefore important for both efficiency and longevity in LED circuits to design the system for proper thermal management.

The junction temperature of an LED (or other electronic component) is directly related to the power being dissipated in the device, the thermal resistance from the device die to the surrounding (ambient) air, and the ambient air temperature. The thermal resistance of a heat transfer path is defined as the opposition to heat transfer through the given path and can be represented by the formula

Where:
Rθ =Thermal Resistance,
ΔT=Temperature Difference (° C.) from one end of the path to the other, and
P=Power Dissipation (W) at the originating point.

Therefore, the rise in the P-N junction temperature of an LED die over the surrounding ambient air temperature is equal to:

T_{Junction}=T_{Ambient}+(Rθ_{Junction-Ambient}*P_{LED}),P_{LED}=V_{F}*I_{F}

Where:
V_{F}=Forward voltage across the LED, and
I_{F}=Forward current through the LED.

From this equation it can be seen that controlling the LED junction temperature requires controlling the power dissipated in the LED in terms of the LED forward voltage and current, the LED junction-to-ambient thermal resistance, and/or the ambient temperature. Since LED light output is directly proportional to the current driven through it, this is a parameter which is not desirably reduced. Also, the forward voltage across the LED is a specification determined by the LED manufacturer. LEDs can be binned for forward voltage, and only specific low V_{F} bins (or ranks) purchased from the manufacturer, however this significantly raises the cost of the LEDs and is usually not practical. Ambient temperature ranges are determined by the operating environment for which the LED product is designed, and in the case of LED lights operating in industry standard fixtures, may not be easily controlled.

This leaves the thermal resistance Rθ_{Junction-Ambient} as the remaining controllable parameter affecting the LED junction temperature. FIG. 3 shows a schematic representation of the thermal path for the heat energy generated in an LED and dissipated in the ambient air. The path is actually made up of several distinct series paths with different thermal resistances. The total thermal resistance of a series heat dissipation path is defined as the sum of the individual thermal resistances, just as electrical resistances add in series. This can be represented as:

Rθ_{1-N}=Rθ₂₋₃+Rθ₃₋₄ . . . +Rθ_{(N-1)-N}

As is shown in FIG. 3, the heat at the LED P-N junction first travels from the die to the LED case, or more accurately to the heat dissipation “slug” manufactured into the LED case. This thermal path is defined as “junction-to-slug”, and its resistance as Rθ_{Junction-Slug}. The heat energy then travels from the LED slug to the circuit board with a thermal resistance of Rθ_{Junction-Slug}, then from the circuit board to the ambient air with a thermal resistance of Rθ_{Board-Ambient}. The total thermal resistance in this typical LED heat dissipation path is then defined as:

Rθ_{Junction-Ambient}=Rθ_{Junction-Slug}+Rθ_{Slug-Board}+Rθ_{Board-Ambient}

Reducing these thermal resistance components is paramount in designing an LED lighting product with high efficiency and long life. Let's examine each one individually.

LED Manufacturers endeavor to produce LEDs with very low Rθ_{Junction-Slug} values. However, as is the case for VF, this is a value specified by the manufacturer, and is not controllable by the design of the end product. Other than selecting LEDs with low Rθ_{Junction-Slug} values, there is nothing that can be done to reduce this parameter. And, often there are other LED parameters which may affect or preclude the selection of LEDs with the lowest Rθ_{Junction-Slug} values.

Rθ_{Slug-Board} is a controllable parameter affected by the attachment method of the LED thermal slug to the circuit board. There are thermal adhesives (tapes and epoxies) which are designed to provide a mechanical bond between two components and provide a relatively low thermal resistance. These have been employed for decades in electronic circuits to attach high-heat generating components to heat dissipating surfaces such as chassis and heat sinks. However, none of the thermal adhesives comes close to the low thermal resistance of solder. It is therefore common in the industry to solder the thermal slug of LEDs and other electronic components so equipped directly to the circuit board.

The final controllable thermal resistance parameter is the Rθ_{Board-Ambient}. Here, a number of techniques have been commonly employed. One common method of reducing the Rθ_{Board-Ambient} is to create a copper pad for soldering the thermal slug, which spreads out and away from the slug, and creates a larger surface area for the heat to be dissipated into the ambient air. FIG. 4 depicts this commonly employed method. Because the thermal energy travels more readily through the copper material of the heat spreader than it does through the fiberglass epoxy resin (FR4 ) of the PCB board, the heat is spread over the surface of the board more effectively. The thermal resistance Rθ_{Board-Ambient} is then reduced because the convective heat transfer from a solid to a fluid (PCB to surrounding ambient air) is enhanced when the surface area is expanded.

The method for reducing Rθ_{Board-Ambient} depicted in FIG. 4 does have merits, and is a common practice in the industry; however, it is limited in its effectiveness due to the small cross sectional area (thickness) of the copper heat spreader pad. On a PCB, this thickness is specified as the copper “weight” of the outer copper layer. Commonly, a ½ oz. or 1 oz. or 2 oz. weight is standard, corresponding to a thickness of 18 μm to 72 μm. Although some PCB manufacturers offer copper weights up to 10 oz. (350 μm thickness), a very high premium in PCB cost is paid for anything other than the standard weights.

Now, the thermal resistance through a solid is inversely proportional to the cross sectional area of the solid, and directly proportional to the length of the solid (distance over which the heat energy must travel), expressed as:

Rθ_{Solid}=R_{λ}*l/A

Where:
R_{λ}=Thermal resistivity of the solid material (K·m/W),
l=Length of solid, and
A=Cross sectional area of solid.

Thermal conductivity is the inverse of resistivity and is expressed in watts per meter Kelvin (W/m·K). Copper has a much higher thermal conductivity than the FR4 PCB board material (approximately 400 W/m·K vs. approximately 0.3 W/m·K). Therefore its thermal resistivity is three orders of magnitude lower than the circuit board, and explains the benefit of a copper etched heat spreader on the surface of the PCB. This method can be further limited however, when the density of circuit components and traces on the top surface of the PCB limits the available area for the heat spreader. In this case, methods have been employed to move the heat spreader to the bottom surface of the PCB.

FIG. 5 shows this method in which the etched copper heat spreader is moved to the bottom of the PCB. In this case, a low thermal resistance path is created from the top surface of the PCB under the LED thermal slug to the bottom surface heat spreader by incorporating thermal vias. A thermal via is similar to an electrical via, but instead of carrying electrical signals from one PCB layer to another, it is placed specifically to carry thermal energy. FIG. 6 shows the same top view PCB circuit as FIG. 4, but with the incorporation of thermal vias directly under the thermal slug mounting pad of the LED. Referencing the thermal via detail drawing of FIG. 7 facilitates an explanation of the use of thermal vias. As shown in FIG. 7, and previously discussed, the PCB base material is FR4 which has a relatively high thermal resistance. The thermal vias are drilled through-holes plated with copper which as previously stated has a thermal conductivity three orders of magnitude higher than the FR4 epoxy. The thermal resistance of n vias can be approximated with the one dimensional heat conduction formula:

Rθ_{Vias}=h/[n·k_{Cu}·π·(D·t−t²)]

Where:
h=the PCB thickness
n=number of vias
k_{Cu}=thermal conductivity of copper
D=diameter of the via
t=thickness of the copper via plating

This thermal resistance can be minimized through the manipulation of the via geometry, placement, and pitch, and can be highly effective in creating a low resistance path for heat conduction through the PCB. An etched heat spreader on the bottom side of the PCB can then be used to maximize surface area for convection of the heat energy into the surrounding air.

Other methods of dissipating heat energy from LEDs in electronic circuits have also been devised and are in common use. These include the use of metal-core printed circuit boards (MCPCB) which typically use an aluminum plate coated with an FR4 or enhanced thermal dielectric isolation layer which then has the etched-copper circuit layer on the top surface. FIG. 8 shows a cross section of an MCPCB.

One of the disadvantages of MCPCBs is their cost, which can be much greater than standard FR4 PCBs. They also typically have a greater manufacturing lead time and are not as readily available as FR4 boards. Another limitation is the single circuit layer available for interconnection. Some manufacturers offer multi-layer MCPCBs, however due to manufacturing complexity and limited availability, these can be prohibitively expensive.

As an alternative to multi-layer MCPCBs, some have employed standard FR4 PCBs using thermal vias and heat spreaders, and laminated these onto aluminum or copper plates. These methods also have drawbacks due to the difficulty of laminating the FR4 board to the metal plate. The lamination material must be thin for proper thermal conduction, but must be in intimate contact with both the PCB surface and the metal surface. Even minor air gaps or bubbles or warping of either surface can greatly hinder the thermal transfer and negate any benefits otherwise gained from the metal plate. Preventing de-lamination through normal expansion and contraction as the circuit heats up is also very difficult due to the differing coefficients of expansion of FR4 and various metals.

One other great drawback exists with all the common methods discussed above. As explained previously, the convection of heat from a solid to a liquid or gas is directly proportional to the surface area of the solid. All the methods above seek to reduce the Rθ_{Board-Ambient} by maximizing the convection surface area (heat spreaders and metal plates which spread the thermal energy over larger portions of the PCB). This however, can cause detrimental effects to other circuit components as they are heated through the spreading of thermal energy from high-power components. Thus, these common methods used to reduce the junction temperature of LEDs and other high-power components can actually increase the junction temperature of surrounding LEDs or components as the heat is spread to them.

Because of the reasons discussed above, there is need in the LED lighting industry for an effective method of dissipating the heat generated by LEDs and other high power components on a PCB into the surrounding air without causing that heat to spread throughout the PCB and damage or adversely affect other components. There is need for such a heat dissipation method to be adaptable to industry standard FR4 circuit boards without the use of expensive MCPCBs. The method should be mechanically and thermally reliable, predictable in its performance, and relatively inexpensive to manufacture.

It is an object of the present invention to provide a solution for removing heat from high-power LEDs and controlling junction temperatures within safe ranges in LED lighting circuits without spreading the thermal energy through the PCB into other circuit components. It is another object of the present invention to be adaptable to inexpensive FR4 PCBs, and to be inexpensive to manufacture. It is a further object of the present invention to be adaptable to small circuits in enclosed spaces such as that found in LED lights conforming to industry standard sizes such as MR11, MR16, R20, PAR30, PAR38, and PAR56.

### BRIEF DESCRIPTION OF THE DRAWINGS

FIG. 1 is a graph showing a typical relationship of relative luminosity to forward current in an LED.

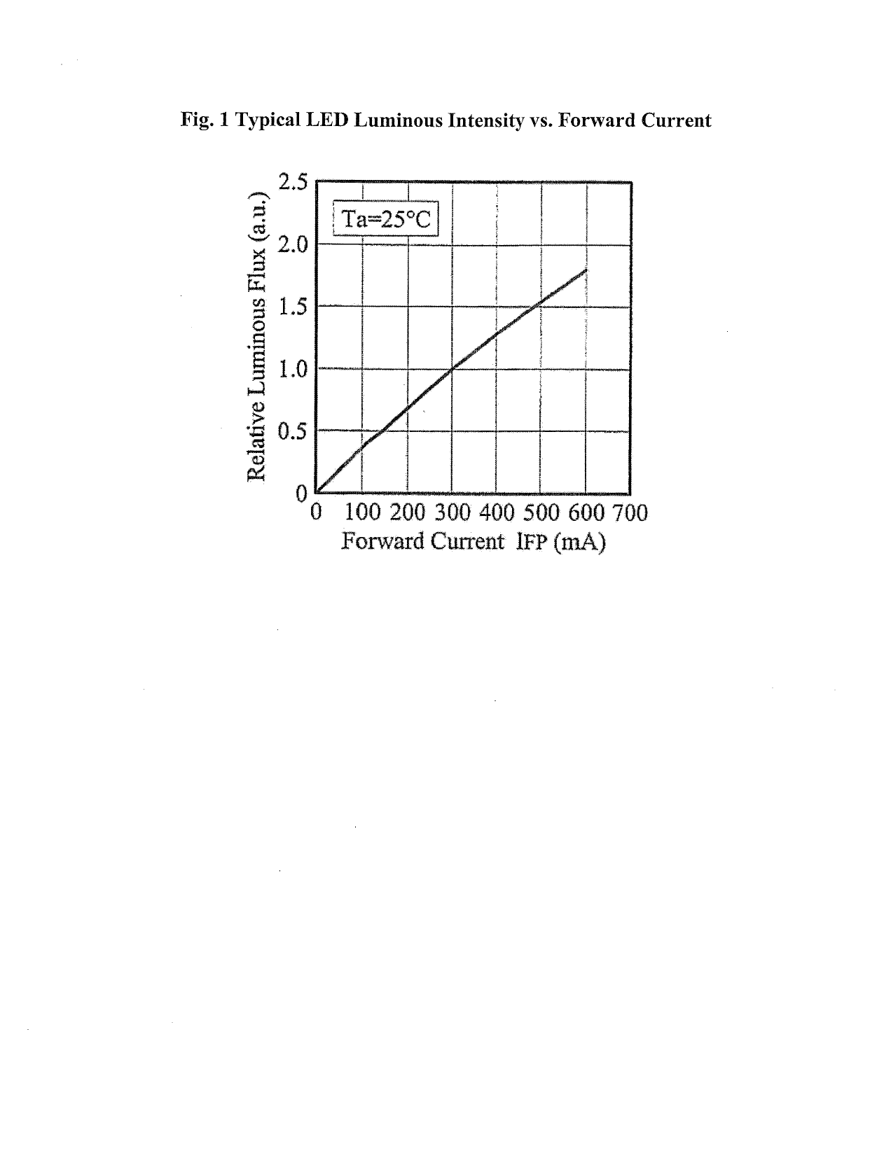

FIG. 2 is a graph showing the typical relative light output of InGaN LEDs as a function of the LED junction temperature.

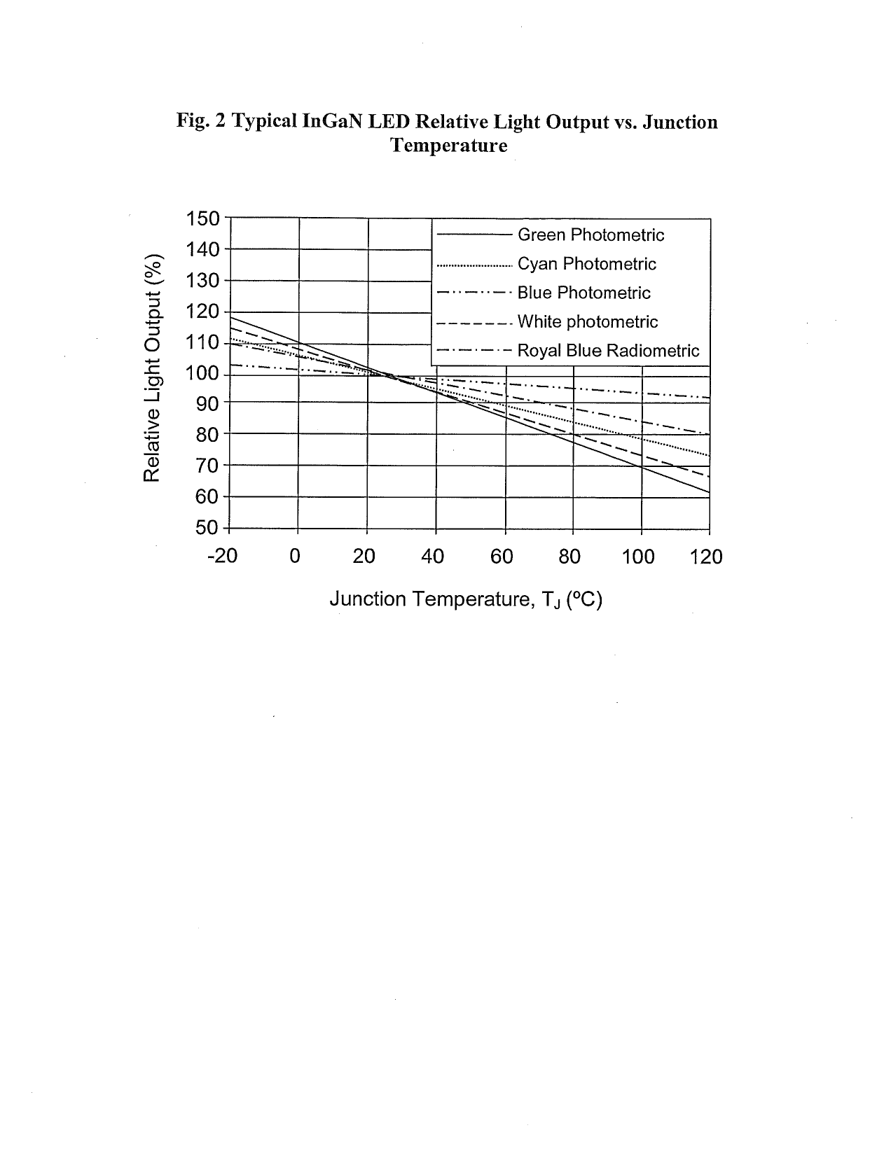

FIG. 3 is a representation of series thermal resistance components making up the thermal dissipation path in a typical LED mounted on a circuit board.

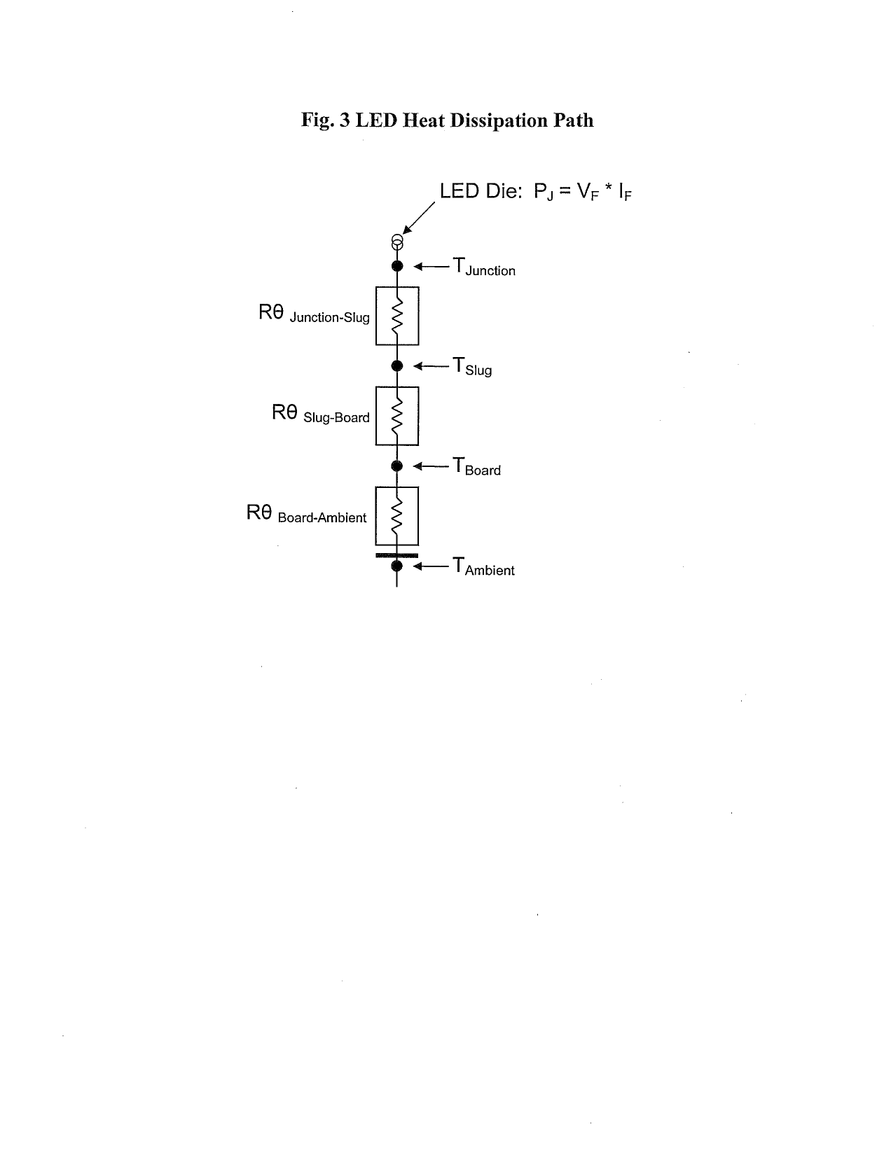

FIG. 4 is a top view of a PCB circuit pattern with an etched copper heat spreader on the LED pad.

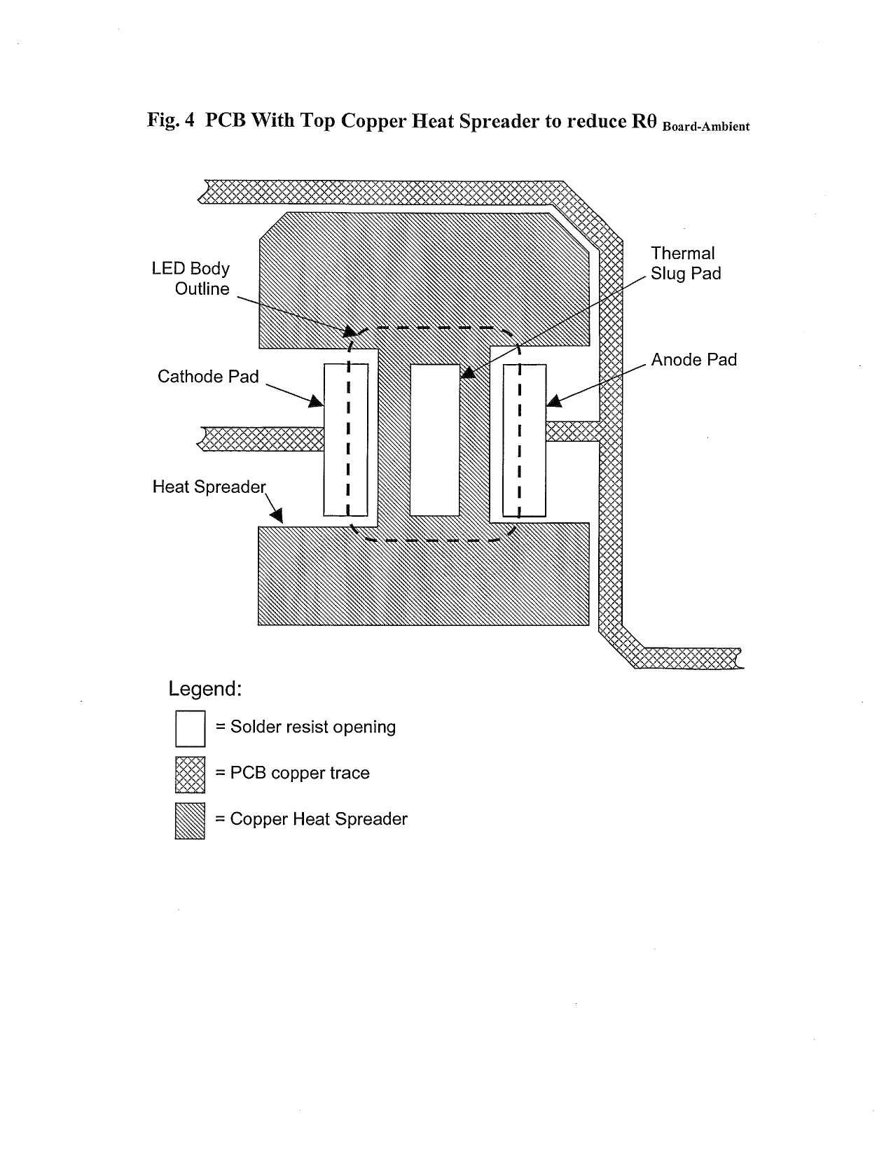

FIG. 5 shows a cross sectional view of a 4-layer PCB with thermal vias under the LED mounting pad.

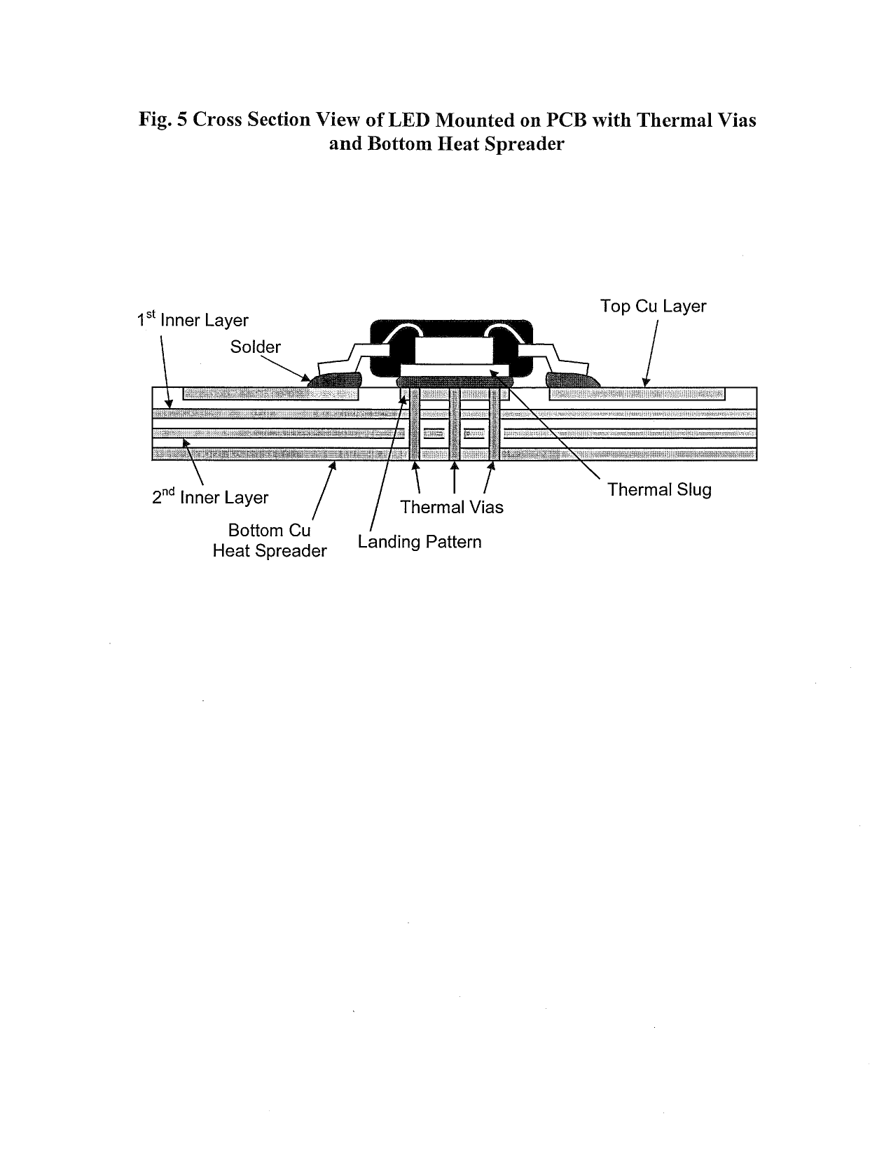

FIG. 6 is the top view PCB circuit pattern of FIG. 4, illustrating thermal vias in the LED landing pattern.

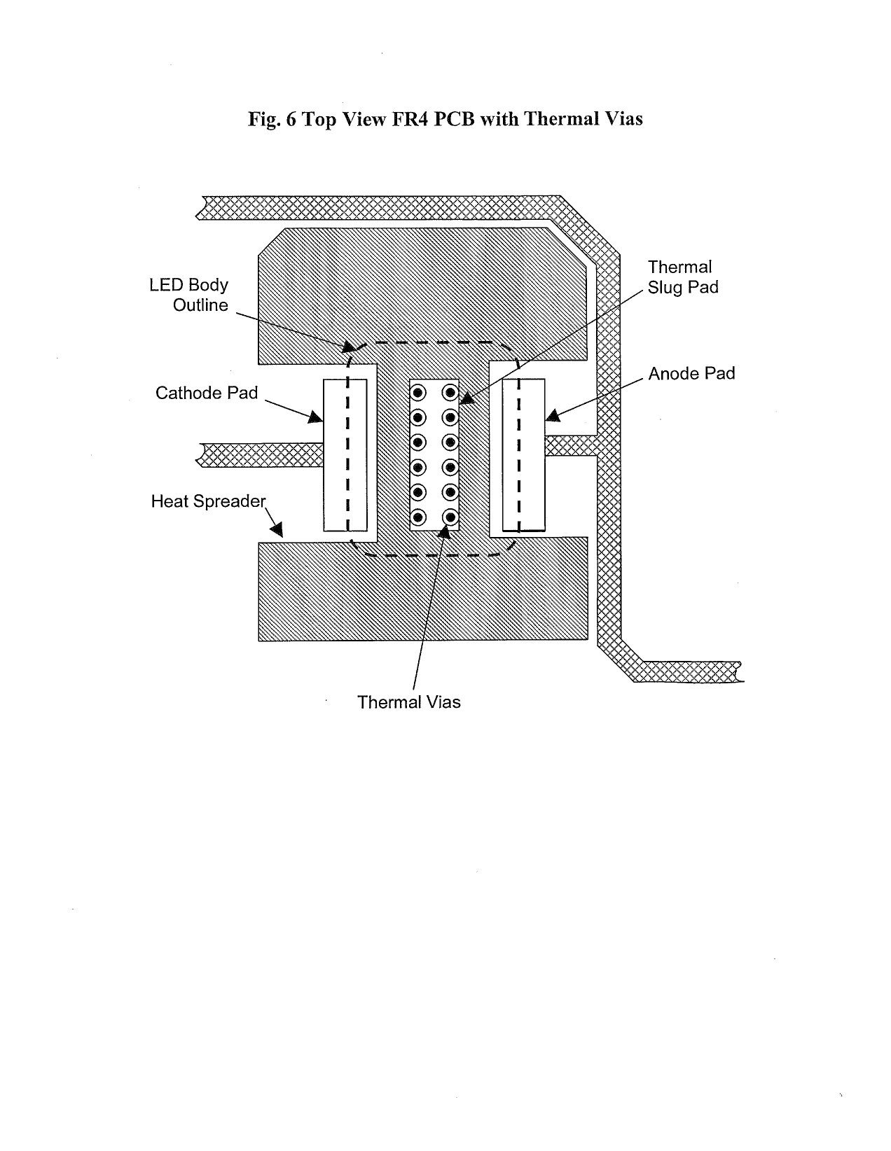

FIG. 7 is a detailed view of the thermal vias of FIG. 6 in cross sectional and top views.

FIG. 8 is a cross sectional view of an LED mounted on a metal core printed circuit board (MCPCB).

FIG. 9 is an illustration of one embodiment of the present invention showing a cross sectional view of the PCB with solder-plugged thermal vias and copper radiators.

FIG. 10 is a detailed view showing the solder-plugged thermal vias of the present invention.

FIG. 11 is an electrical circuit diagram of a typical high-power surface mount LED.

FIG. 12 is a cross sectional view of an alternate embodiment of the present invention showing an LED circuit similar to FIG. 9, but with a solder-attached shared copper radiator.

FIG. 13 is a circuit diagram of a typical multiple LED device.

FIG. 14 is the multiple LED circuit diagram of FIG. 13, showing the effect of the solder-attached shared copper radiator of FIG. 12.

FIG. 15 is a table showing the thermal conductivity of various lead-free solders.

FIG. 16 is a diagram of the thermal dissipation path in a multiple LED circuit on a MCPCB.

FIG. 17 is a diagram of the thermal dissipation path in one embodiment of the present invention.

### SUMMARY OF THE INVENTION

The present invention is directed to a method of heat sinking LEDs and other high powered electronic components using a copper radiator soldered directly under the component on the opposite side of the PCB using solder-plugged thermal vias to conduct heat from the component thermal slug through the PCB to the copper radiator. An advantage of the present invention is that the radiator is isolated from other LEDs and circuit components and does not spread the thermal energy to the other components mounted on the PCB. A further advantage of the present invention is that it uses solder to attach the copper radiator to the PCB, which has much higher thermal conductivity than epoxies, thermal tapes and other attachment methods, while remaining electrically isolated from other circuit components. A still further advantage of the present invention is that the thermal vias are plugged with solder, thereby increasing the thermal conductivity of the vias over standard copper plated thermal vias. Further advantages of the invention will become apparent to those of ordinary skill in the art through the disclosure herein.

### DETAILED DESCRIPTION OF THE INVENTION

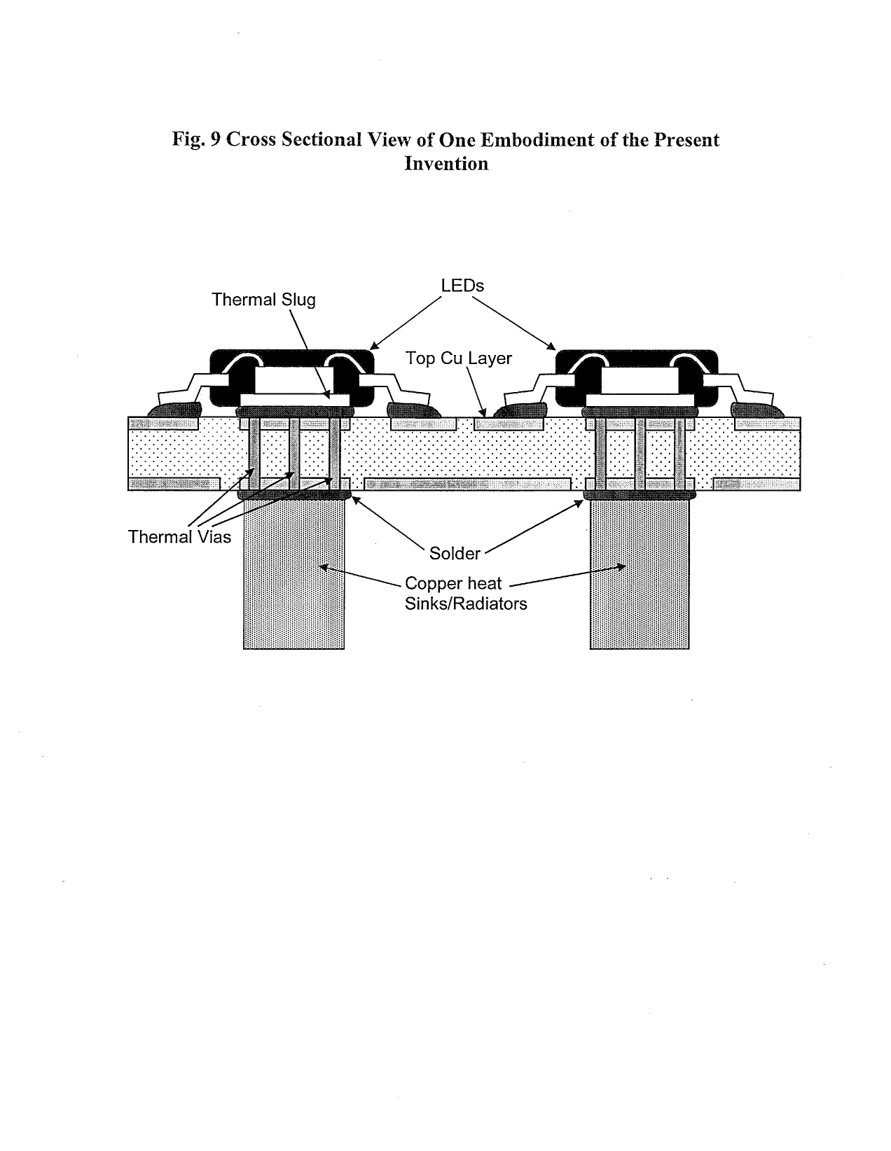

FIG. 9 shows a cross sectional view of one embodiment of the current invention. As shown in FIG. 9, thermal vias are placed in the PCB directly under the solder pad landing patterns for the LED thermal slugs. The thermal vias conduct heat from the thermal slugs of the LEDs to the bottom surface of the PCB where landing patterns have been added to accept copper heat sinks. The copper heat sinks are soldered to the landing patterns on the bottom surface of the PCB and function as thermal radiators to radiate the thermal energy into the surrounding ambient air. Sufficient solder is used to attach both the LEDs to the top surface and the copper heat sinks to the bottom surface of the PCB so as to wick into and fill the thermal vias.

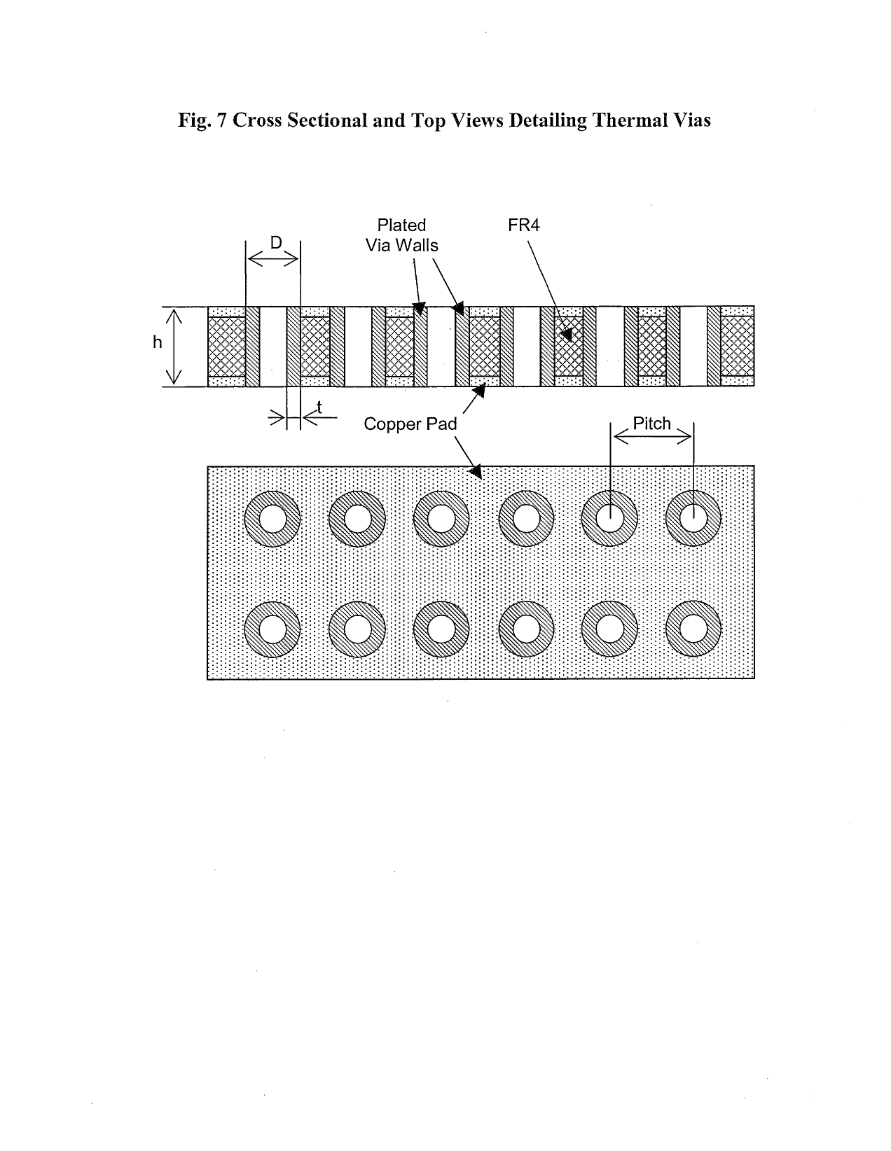

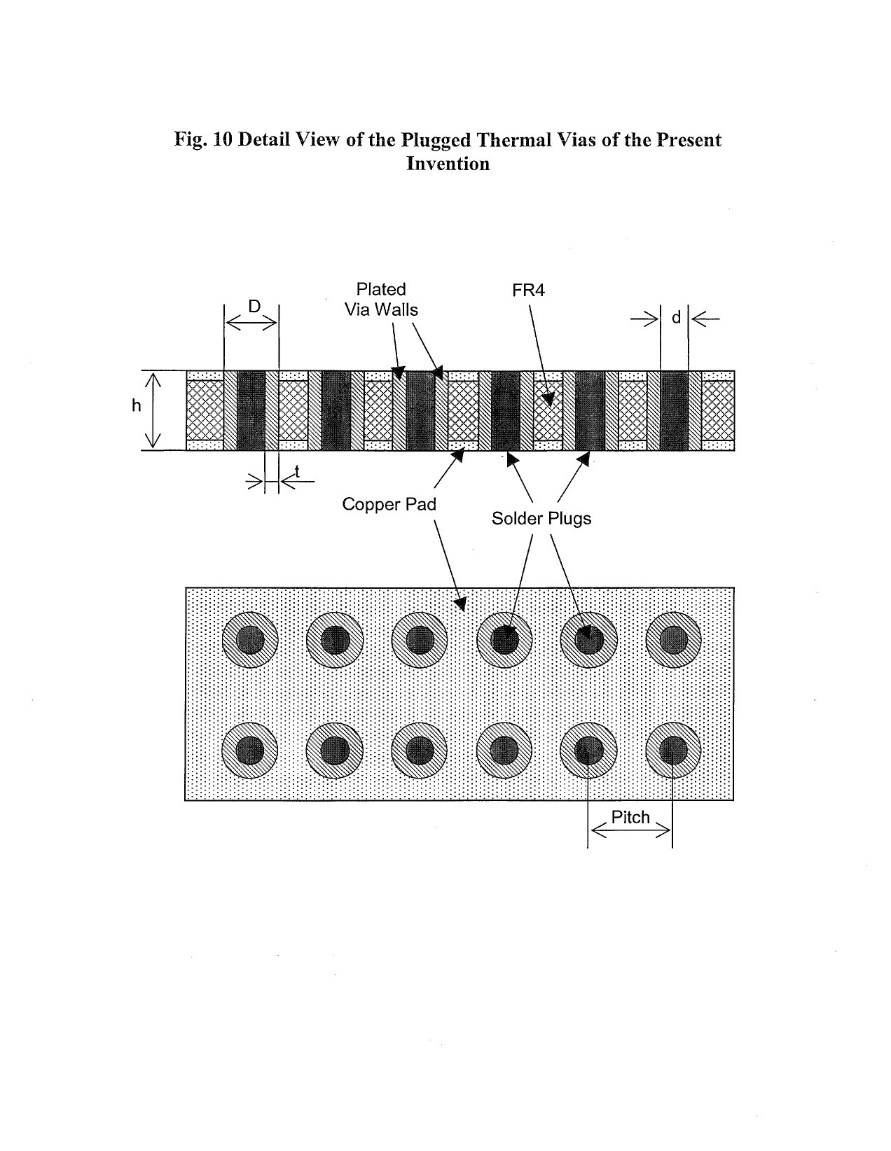

FIG. 10 shows a detailed view of the solder-plugged thermal vias. In the Background Section it was shown from FIG. 7, that the thermal resistance of n vias can be approximated with the one dimensional heat conduction formula:

Rθ_{Vias}=h/[n·k_{Cu}·π·(D·t−t²)]

Where:
h=the PCB thickness
n=number of vias

k_{Cu}=thermal conductivity of copper

D=diameter of the via

t=thickness of the copper via plating

Taking the inverse of this formula, we can see that the thermal conductance of the same n vias is:

λ=[n·k_{Cu}·π·(D·t−t²)]/h(W/°C.)

Now, referring to FIG. 10, we have the same via construction, geometry, and count as in FIG. 7. However, the vias shown in FIG. 10 are now plugged with solder. We can now perform the same one dimensional heat conduction analysis to determine the new thermal conductance for these n plugged vias:

λ=[n·k_{Cu}·π·(D·t−t²)]/h+(n·k_{Solder}·π·d²/4)/h(W/°C.)

And, from FIG. 10, we can determine that the diameter of the solder plug inside the via is equal to the via diameter minus twice the via wall thickness. That is:

d=D−2t

Therefore:

λ=n·π/h·[k_{Cu}·(D·t−t²)+K_{Solder}·(D²/4−Dt+t²)](W/°C.)

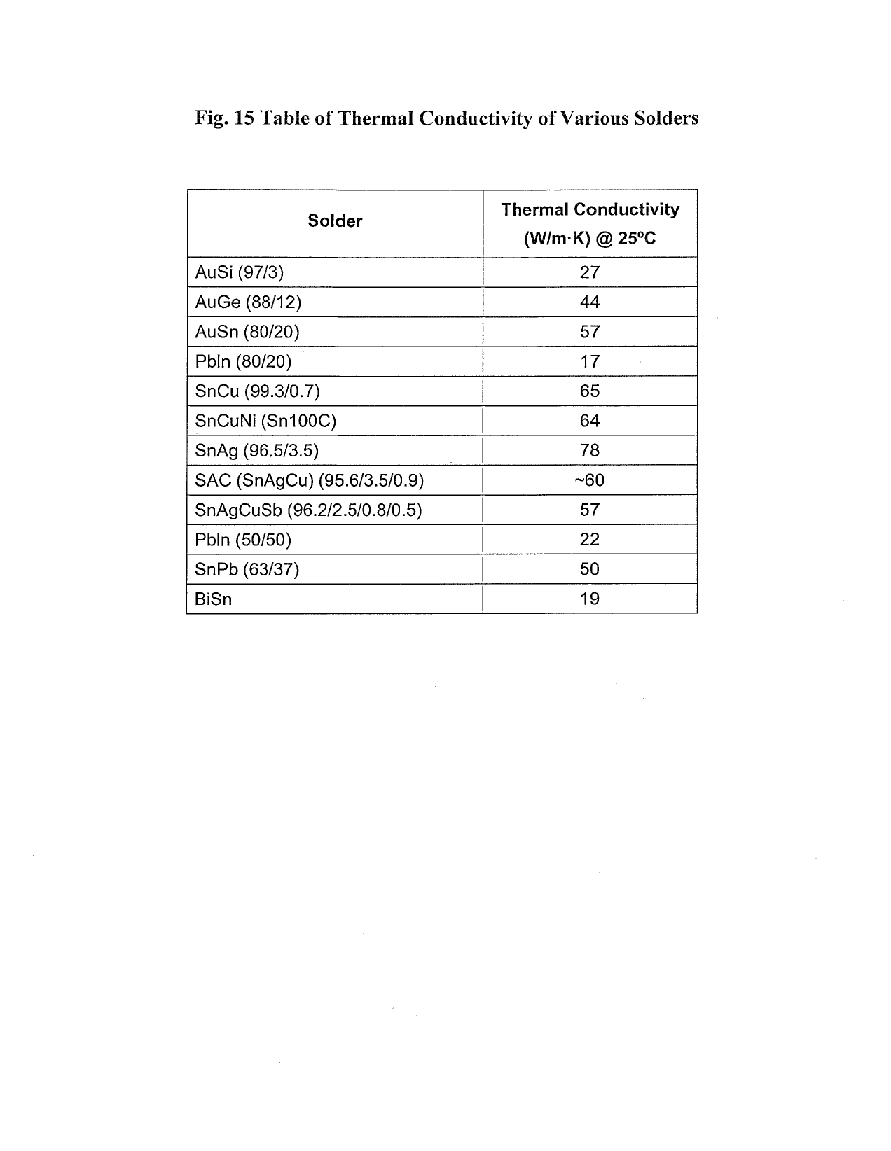

So, clearly the thermal conductance of the n vias has been increased due to the conductivity of the solder filling the vias, which can be seen from FIG. 15 to be in the range of 20-80 W/m·K, depending on the specific solder used. Since non-plugged vias have air in the via center, no heat conduction occurs through the center of the via. From these formula results, it is clear that by increasing the size of the vias, or decreasing the pitch between vias so that there are a greater number in the same area, the thermal conductance through the PCB can be greatly increased over that of the FR4 board material.

As stated in the Background section, the thermal conductivity of copper is three orders of magnitude greater than that of FR4 , and from the table of FIG. 15 it can be seen that the thermal conductivity of solder is two orders of magnitude higher than FR4 . So, in addition to adding thermal vias to conduct heat from the top to the bottom of the PCB as is common in the industry, the present invention maximizes this heat conduction by filling the vias with solder.

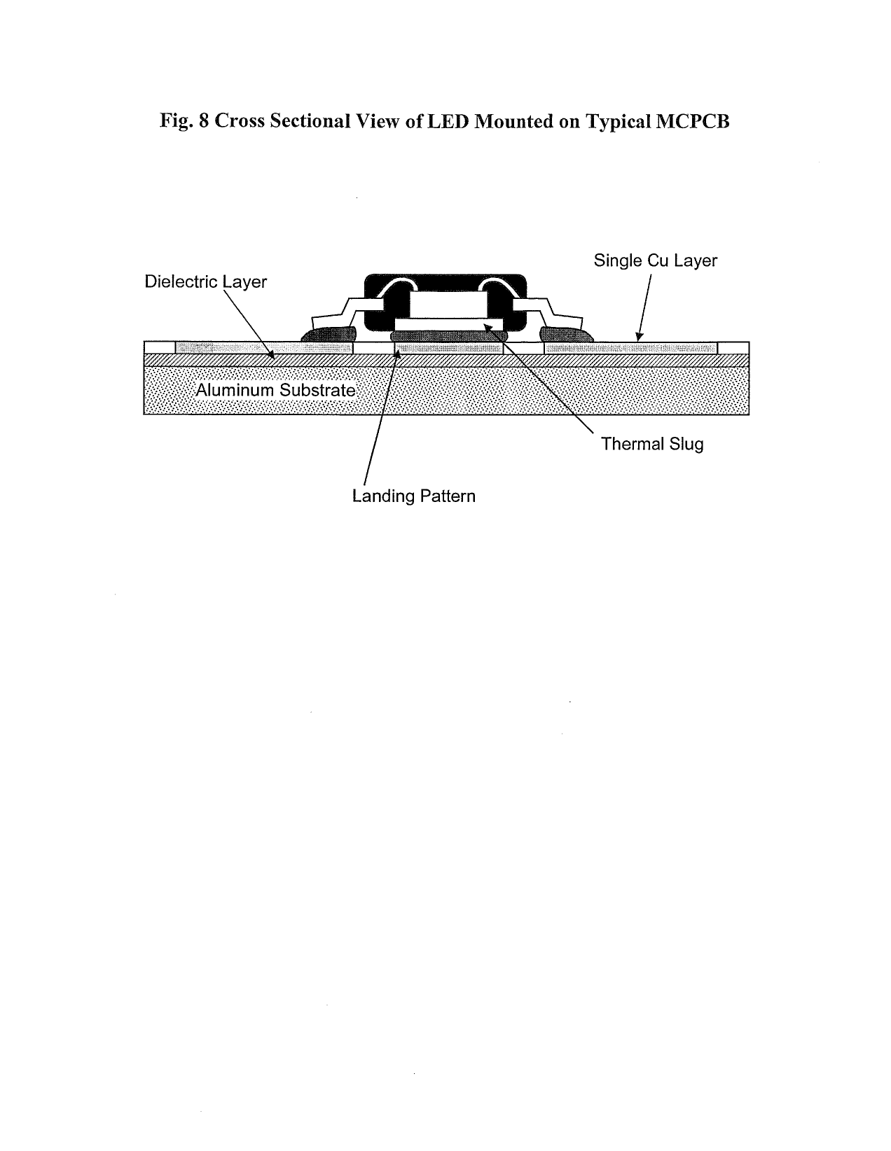

As was discussed in the Background section, other methods of placing metal heat sinks and radiators on the bottom of circuit boards have been devised and are in common use, such as metal-core PCBs (MCPCBs), or lamination of FR4 PCBs onto aluminum plates or other radiators. One of the disadvantages of these common methods is that an electrically isolating layer (dielectric) must exist between the circuit and components, and the radiator. This dielectric layer is shown in the MCPCB cross section shown in FIG. 8. Without this electrical isolation, the thermal radiator would short the electrical circuit.

The disadvantage of this electrical isolation is apparent from an understanding of the properties of materials. The materials that make good thermal conductors also make good electrical conductors, and the materials that make good dielectrics generally make poor thermal conductors. Companies such as Bergquist have developed specialized dielectrics with thermal conductivities two to three times that of standard FR4, however, this is still two orders of magnitude lower than solder.

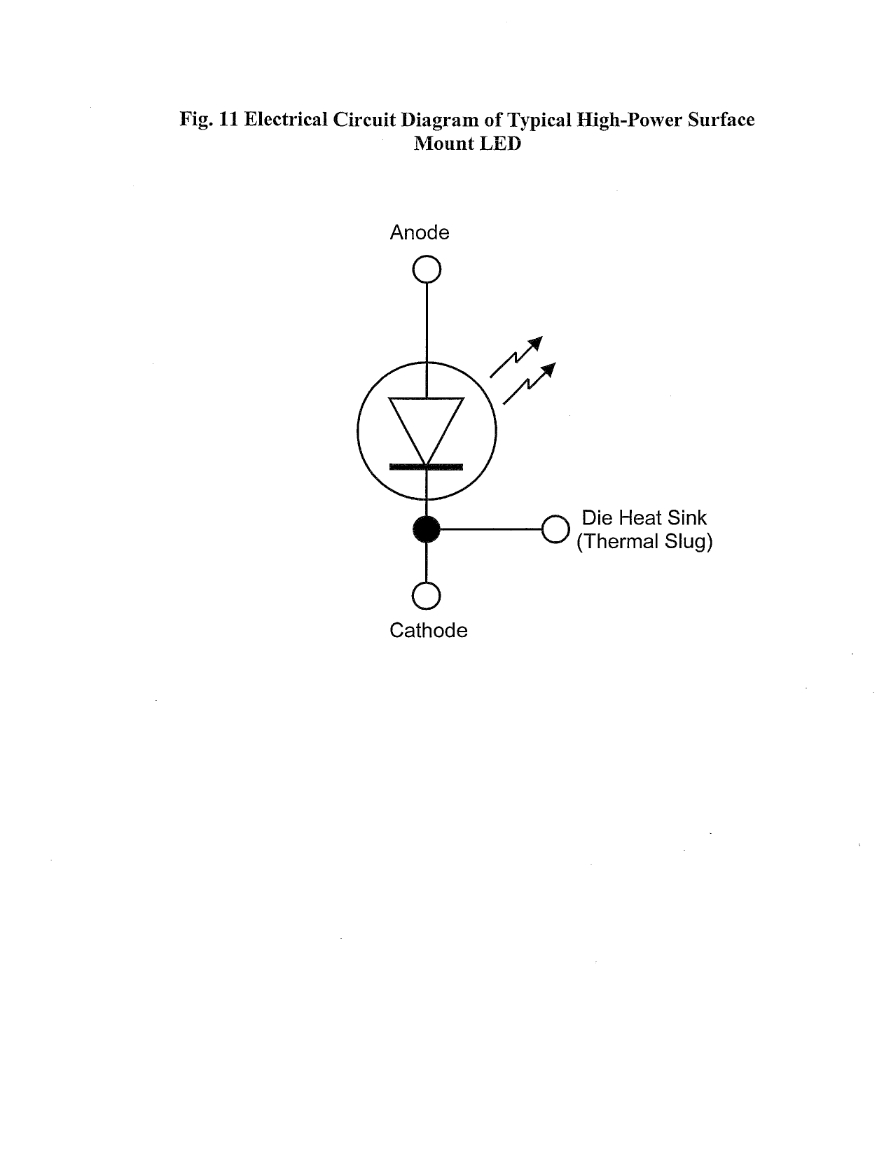

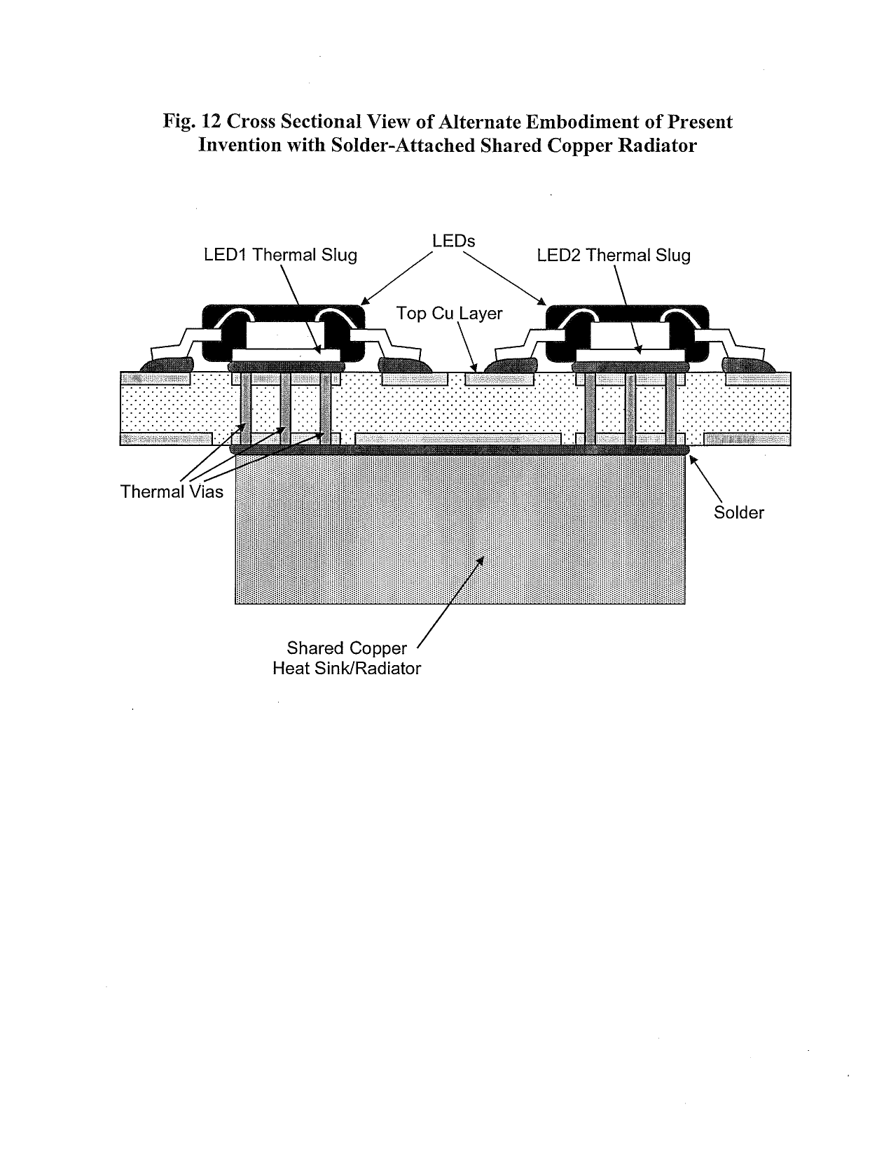

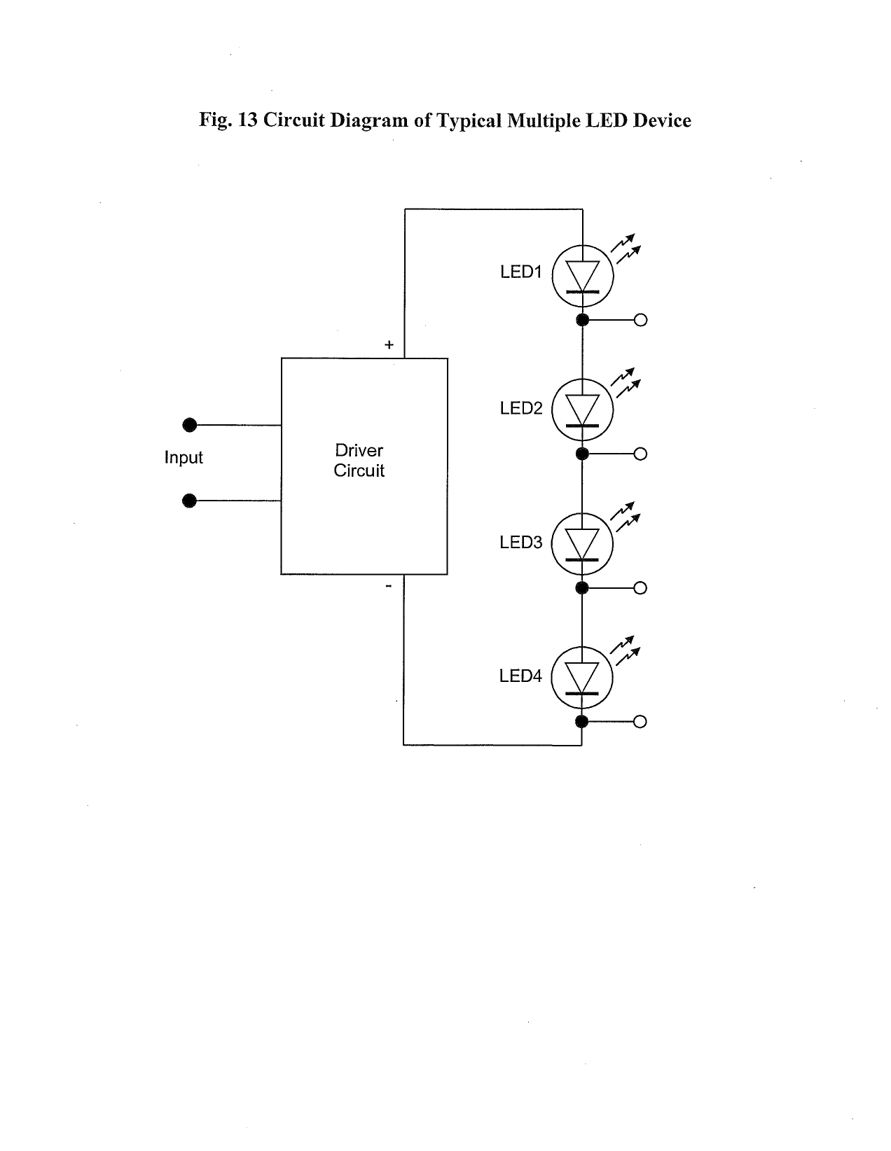

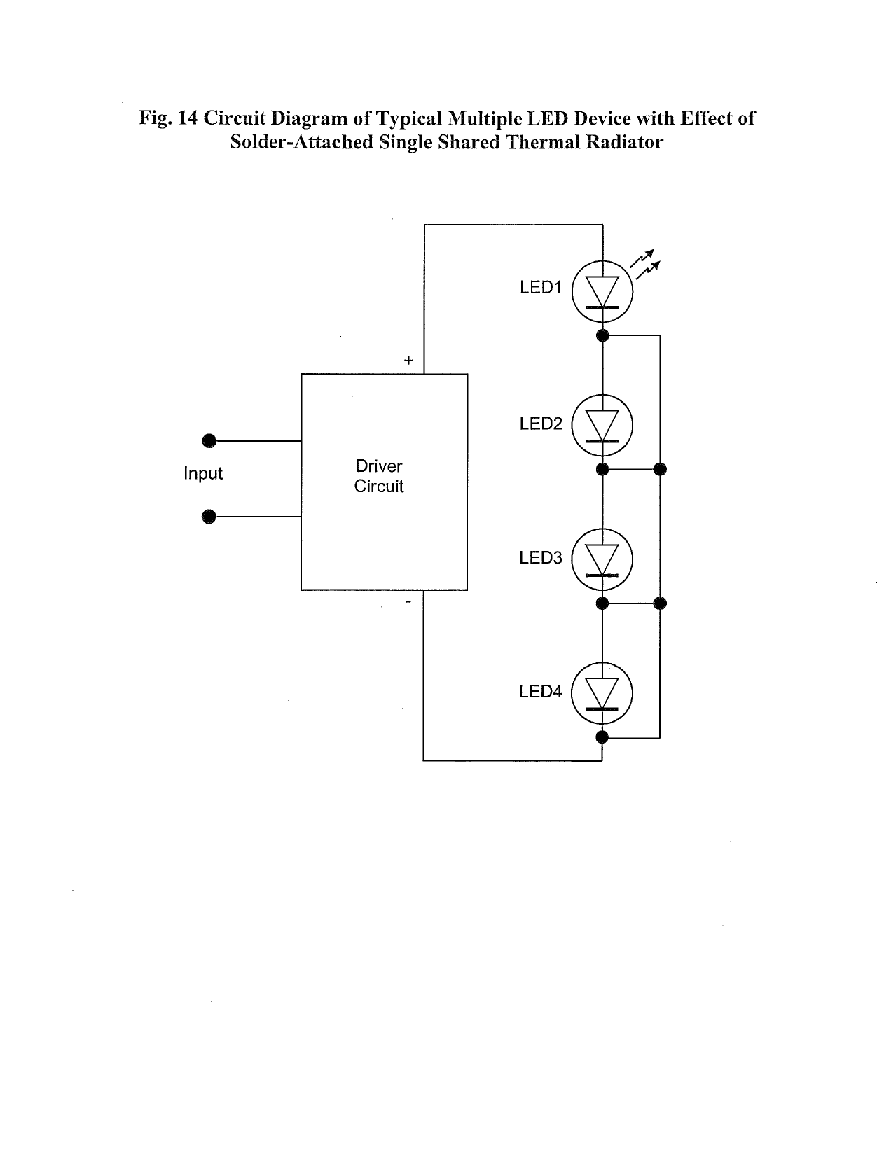

The present invention facilitates the use of separate thermal radiators for each of the LEDs or other high-power components. As can be seen in FIG. 9, this allows the use of solder as the mechanical and thermal attachment method for the thermal radiator without compromising electrical isolation between circuit components. Often, there is a need for electrical isolation in the case of high-power LED circuits, as the thermal slug in many high-power LEDs is not electrically neutral. FIG. 11 shows the electrical circuit diagram of a common high-power surface-mount LED with a non-electrically neutral thermal slug. The LED represented in this diagram has its thermal slug electrically tied to the cathode lead of the LED as often occurs in the industry. FIG. 13 shows a typical circuit diagram of a multiple LED device implemented with this type of LED. If this circuit were executed on an FR4 PCB with thermal vias under the thermal slugs of the LEDs and a common heat sink bonded to the bottom of the PCB without a dielectric, such as is shown in FIG. 12, each of the LED thermal slugs would be electrically connected. This would result in electrically connecting each of the LEDs' cathodes together as is shown in the circuit diagram of FIG. 14. It is obvious from the circuit diagram of FIG. 14 that LED2, LED3, and LED4 are shorted out by the heat sink.

The present invention as shown in the embodiment of FIG. 9 is particularly adaptable to this type of LED since individual heat sinks can be used for each component. It should be noted however, that the present invention is not limited to this configuration, and in the case of LEDs or other high-power components that do have electrically neutral thermal slugs, the configuration shown in FIG. 12 is an acceptable alternative and should be considered as another embodiment of the present invention.

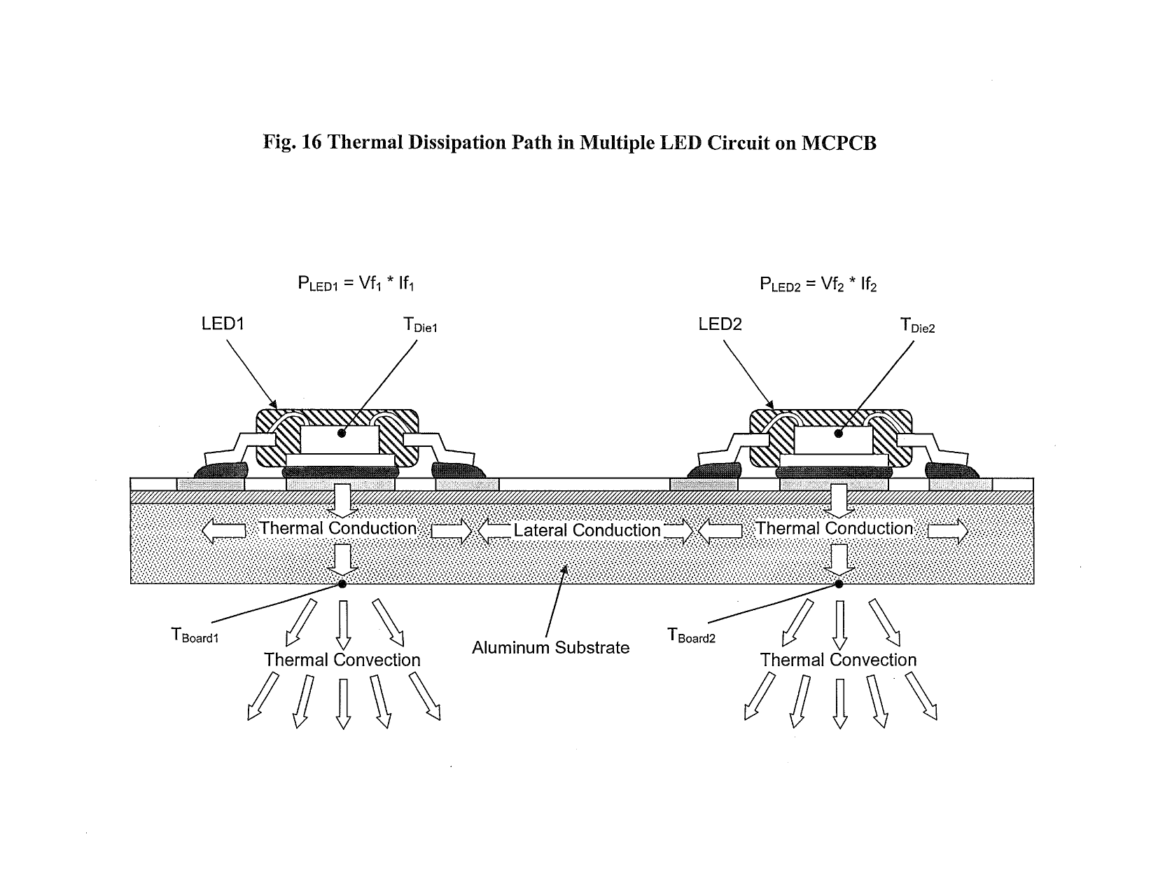

Another advantage of the present invention over MCPCBs or other bonded thermal plate solutions is that the isolated heat sinks of the present invention allow for direct radiation into the ambient air from each thermal “hot spot” without the disadvantage of first conducting the thermal energy across the PCB and into other circuit components. An examination of the typical MCPCB solution in FIG. 16 for a multiple LED circuit shows that the aluminum plate while acting as a heat sink also acts as a heat spreader as some of the thermal energy conducts laterally through the plate under the entire circuit. So some of thermal energy from LED1 in FIG. 16 is conducted under LED2, reducing the conduction of thermal energy from LED2, and vice versa.

Referencing FIG. 16 we can further understand this reduction of the thermal conduction rate from each LED on a MCPCB due to lateral conduction in the aluminum substrate. As the junction temperature T_{Die1} of LED1 increases due to its power dissipation, the thermal energy will conduct into the PCB and to the bottom surface as explained in the Background section, according to the thermal resistance formula:

Rθ=ΔT/P

### Where:

Rθ=Thermal Resistance of the conduction path,
ΔT=Temperature Difference (°C.) from one end of the path to the other, and
P=Power Dissipation (W) at the originating point.

We have seen that the thermal resistance of the conduction path from the LED die to the bottom of the PCB has several components due to the varying materials in the path, but for this discussion we need only be concerned with the overall Rθ for the path, here denoted Rθ_{LED Junction-MCPCB Bottom}. Therefore, the dissipation from LED1 to the bottom of the PCB in FIG. 16 can be represented by the thermal resistance formula:

Rθ_{LED1 Junction-MCPCB Bottom}=(T_{Die1}−T_{Board1})/P_{LED1}

And, for LED2:

Rθ_{LED2 Junction-MCPCB Bottom}=(T_{Die2}−T_{Board2})/P_{LED2}

Solving for junction temperatures, we can see that:

T_{Die1}=P_{LED1}*Rθ_{LED1 Junction-MCPCB Bottom}+T_{Board1}

And:

T_{Die2}=P_{LED2}*Rθ_{LED2 Junction-MCPCB Bottom}+T_{Board2}

We can see that the junction temperatures of the LEDs are directly affected by the temperature of the board surface under the LEDs into which the heat is being conducted. Now, as the aluminum substrate of the MCPCB conducts some of the heat laterally, the temperature at location T_{Board1} will increase due to the thermal energy of LED2, and T_{Board2} will increase due to the thermal energy of LED1. Therefore, the junction temperatures TDie1 and TDie1 will increase due to the conducted thermal energy from each other. For circuits with higher densities of high-power LEDs and other hot components, this effect can be great.

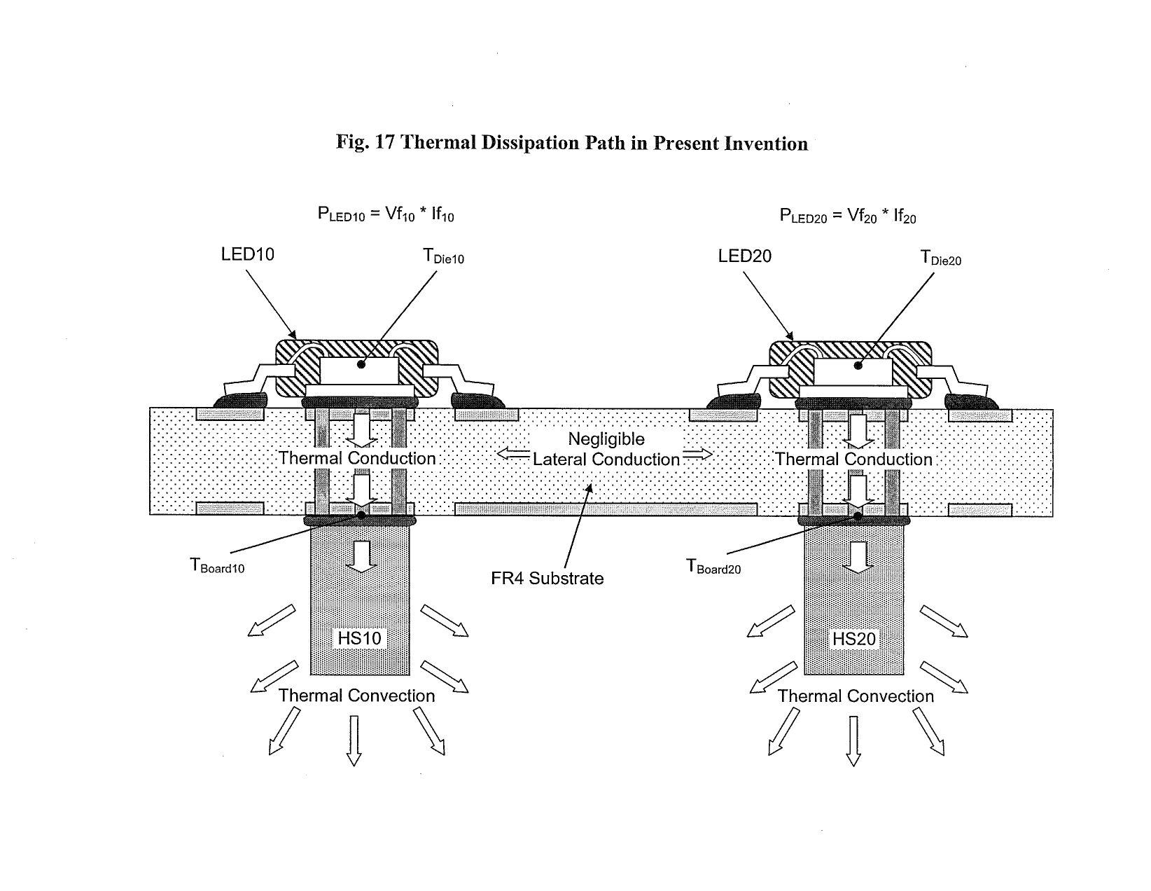

Now, referencing FIG. 17 we can see the thermal path for heat dissipation in the present invention. As discussed previously, the conduction from the top of the PCB to the heat sinks is greatly improved due to the solder-filled thermal vias providing a thermal conductivity several orders of magnitude greater than that of the FR4 PCB material. This results in a thermal conduction from LED10 to heat sink HS10 and from LED20 to heat sink HS20 which is several orders of magnitude greater than any thermal conduction laterally through the PCB. This differs from the case of the MCPCB detailed in FIG. 16 where the same contiguous material (aluminum) exists to conduct the heat to the bottom of the board and laterally through the board, with the same thermal conductivity k_{A1}.

Because the lateral thermal conduction through the PCB in the present invention is negligible, the LEDs and other high-power components have negligible affect on the thermal conduction of each component. This allows a greater density of LEDs and high-power components on the PCB, facilitating smaller form factors for the LED circuits which allows the present invention to be adaptable to smaller enclosed spaces such as that found in LED lights conforming to industry standard sizes such as MR 11, MR 16, R20, PAR30, PAR38, and PAR56.

Since the thermal resistance of the thermal vias was shown above to be directly proportional to the length of the vias, and the via length is determined by the PCB thickness, the present invention is preferably adapted to thinner circuit boards, especially 0.031″ (0.8 mm) which is an industry standard. However, it is obvious to anyone skilled in the art that other PCB thicknesses could also be used to implement the present invention.

It is also obvious to anyone skilled in the art that although the above description of the invention mentioned only FR4 PCBs which are the most common in the industry, the invention can be implemented on a PCB made of any common laminate material such as FR2, Composite Epoxy Materials (CEM), BT-Epoxy, Polyimide, Cyanate Ester, and PTFE (Teflon).

What is claimed is:

1. A thermal dissipation method for high-power circuit components on printed circuit boards comprising:
One or more landing pattern pads adapted to accept the case-molded thermal slugs of said high-power components through standard solder attachment methods, and
one or more heat sink solder pads on the opposite side of said printed circuit board adapted to accept copper heat sinks through said standard solder attachment methods, and
one or more thermal vias connecting said landing pattern pads to said heat sink solder pads,
said thermal vias filled and plugged with said solder, and providing a thermal conduction path of relatively low thermal resistance through said printed circuit board between said components and said heat sinks

2. The thermal dissipation method of claim 1 providing
electrical isolation between non-electrically neutral types of said thermal slugs of said high-power components through physical separation between said heat sinks.

3. The thermal dissipation method of claim 1 wherein
said high-power circuit components include one or more LEDs.

4. The thermal dissipation method of claim 3 wherein
said circuit board and said high-power components form a luminary device.

5. The thermal dissipation method of claim 4 wherein
said luminary device conforms to an industry standard light size and base.

6. The thermal dissipation method of claim 5 wherein
said luminary device is an MR11 LED light.

7. The thermal dissipation method of claim 5 wherein
said luminary device is an MR16 LED light.

8. The thermal dissipation method of claim 5 wherein
said luminary device is an R20 LED light.

9. The thermal dissipation method of claim 5 wherein
said luminary device is a PAR30 LED light.

10. The thermal dissipation method of claim 5 wherein
said luminary device is a PAR38 LED light.

11. The thermal dissipation method of claim 5 wherein
said luminary device is a PAR56 LED light.
